(19) United States
(12) Patent Application Publication
(10) Pub. No.: US 2011/0241743 A1
(43) Pub. Date: Oct. 6, 2011

(54) APPARATUS AND METHOD FOR SYNCHRONIZING TIMING CLOCK BETWEEN TRANSMISSION SIGNAL AND RECEPTION SIGNAL

(75) Inventors: Ho-Min Eum, Daejeon (KR); Heung-Mook Kim, Daejeon (KR); Soo-In Lee, Daejeon (KR)

(73) Assignee: ELECTRONICS AND TELECOMMUNICATIONS RESEARCH, Daejon (KR)

(21) Appl. No.: 13/133,382

(22) PCT Filed: Dec. 8, 2009
(86) PCT No.: PCT/KR2009/007322

§ 371 Date: Jun. 7, 2011

(30) Foreign Application Priority Data
Dec. 8, 2008 (KR) 1020080124308
Apr. 8, 2009 (KR) 1020090030317

(51) Int. Cl. H03L 7/00

(52) U.S. Cl. 327/161; 327/141

(57) ABSTRACT

Provided are an apparatus and method for synchronizing a timing clock between a transmission signal and a reception signal. The apparatus for synchronizing a timing clock includes a timing restorer configured to restore a timing clock based on a digital input data; and a timing clock synchronizer configured to synchronize the timing clock based on timing information and a timing restoration signal restored in the timing restorer.

### TECHNICAL FIELD

The present invention relates to an apparatus and method for synchronizing a timing clock between a transmission signal and a reception signal; and, more particularly, to timing clock synchronizing a apparatus and method which embodies a timing restoration unit of a receiver in digital and embodies the timing clock synchronization between a reception signal and a transmission signal in digital, to thereby improve performance of a demodulator and quality of a relay signal in a relay station.

### BACKGROUND ART

Generally, a relay is installed in an area which a signal of a main transmitter is received weakly. The relay resolves a problem of weak signal reception in a shadow area and expands the signal transmission area of the main transmitter. The relay receives a signal, processes the received signal in digital or analog and transmits the processed signal. Among relays for digital signal processing, a relay demodulates a reception signal, re-modulates the reception signal, and transmits the re-modulated signal is called a regenerative relay.

In case of the regenerative relay the demodulated signal in a receiver affects the quality of a transmission signal. Thus, performance of the relay depends greatly on the demodulation performance of a demodulator. Specifically, a timing restoration unit is embodied in a hybrid of digital and analog or all in digital. When a signal is received and not transmitted again, the demodulator is generally embodied in digital to improve reception performance and stability. Here, all digital embodiments mean that a fixed local oscillator is used in a process of analog-to-digital conversion (ADC). Here, since the entire demodulator is fully operated by a digital signal processing using the fixed local oscillator, the demodulator may have improved reception performance.

When the demodulated reception signal is re-transmitted, it is important to synchronize a timing clock between a transmission signal and a reception signal. If the timing restoration unit is embodied in a hybrid of digital and analog, the timing clock between the transmission signal and the reception signal is synchronized naturally. Here, the digital-to-analog hybrid type timing restoration unit is realized by sharing a variable local oscillator, which is controlled by the timing restoration unit, with analog-to-digital conversion process of the receiver and digital-to-analog conversion process of the transmitter. The digital-to-analog hybrid type timing restoration unit is easily realized, but it is inferior to a digital type timing restoration unit in transmission and reception performance.

Performance of the repeater is evaluated by the quality of a transmission signal, and the quality of the transmission signal depends on the performance of the receiver, especially, the performance of the demodulator. In order that the demodulator has good performance, the timing restoration unit of the demodulator should be embodied all in digital. In this case, it is not easy to synchronize the timing clock between a reception signal and a transmission signal. Therefore, it is required to develop technology for synchronizing the timing clock between the reception signal and the transmission signal.

### DISCLOSURE OF INVENTION

### Technical Problem

An embodiment of the present invention is directed to solve a problem that it is difficult to synchronize the timing clock between a reception signal and a transmission signal when a timing restoration unit of a demodulator is embodied all in digital.

An embodiment of the present invention is directed to provide an apparatus and method for synchronizing a timing clock between a reception signal and a transmission signal that can improve reception performance as well as quality of the transmission signal by embodying a timing restoration unit of a receiver all in digital and embodying synchronization of the timing clock between the reception signal and the transmission signal in digital.

Another embodiment of the present invention is directed to provide an apparatus and method for synchronizing a timing clock between a reception signal and a transmission signal that can reduce complexity of embodying the apparatus for synchronizing a timing clock, provide exact synchronization of the timing clocks between a reception signal and a transmission signal, and increase transmission efficiency.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Solution to Problem

In accordance with an embodiment of the present invention, there is provided an apparatus for synchronizing a timing clock between a transmission signal and a reception signal, including: a timing restorer configured to restore a timing clock based on a digital input data; and a timing clock synchronizer configured to synchronize the timing clock based on timing information and a timing restoration signal restored in the timing restorer.

In accordance with another embodiment of the present invention, there is provided a method for synchronizing a timing clock between a transmission signal and a reception signal, including: sampling the reception signal; restoring a timing clock based on the sampled data and outputting a timing restoration signal and restored timing information; and synchronizing the timing clock based on the restored timing information and the timing restoration signal.

### Advantageous Effects of Invention

The above present invention can improve reception performance as well as quality of a transmission signal by embodying a timing restoration unit of a receiver all in digital and embodying synchronization of a timing clock between the reception signal and the transmission signal in digital.

Moreover, the present invention can reduce embodiment complexity, provide exact timing clock synchronization between a reception signal and a transmission signal, and increase transmission efficiency.

### BRIEF DESCRIPTION OF DRAWINGS

FIG. 1 is a block diagram showing an apparatus for synchronizing a timing clock of a transmission signal and a reception signal in accordance with an embodiment of the present invention.

FIG. 2 illustrates timing clock synchronization scheme in accordance with an embodiment of the present invention.

FIG. 3 is a flowchart describing a method for synchronizing timing clock between a transmission signal and a reception signal in accordance with an embodiment of the present invention.

### BEST MODE FOR CARRYING OUT THE INVENTION

Exemplary embodiments of the present invention that can be easily embodied by those skilled in the art will now be described in detail with reference to the accompanying drawings. The invention, however, may be embodied in many different forms and should not be construed as being limited to the embodiments set forth herein. In the accompanying drawings, a portion irrelevant to a description of the present invention will be omitted for clarity. Moreover, like reference numerals refer to like elements throughout the present specification.

First, points of the present invention will be described as follows.

An apparatus and method for synchronizing a timing clock between a reception signal and a transmission signal in accordance with an embodiment of the present invention (which is referred to as “timing clock synchronization apparatus and method”) is applied to a repeater that processes the reception signal and transmits the transmission signal. The timing clock synchronization apparatus and method uses a fixed local oscillator instead of a variable local oscillator which is controlled by a timing restoration unit of a receiver and a digital-to-analog converter of a transmitter. The timing clock synchronization apparatus and method generates the transmission signal based on timing information of the receiver and a second interpolator to synchronize the timing clock between the reception signal and the transmission signal. The timing information is the timing clock information restored by the timing restoration unit.

If the digital-to-analog converter of the receiver in the repeater uses the fixed local oscillator, the receiver and the transmitter operate according to the same system clock. Here, the system clock has a regular period and a higher frequency than the timing clock to be restored because it is generated by the fixed local oscillator. An average frequency of the timing clock which is restored by the timing restoration unit is a value synchronized with the generated timing clock in the transmitter. However, the period of the restored timing clock is not always fixed because the timing restoration unit operates according to the system clock. That is, if n system clocks are generated within a predetermined time, valid data is generated at only m (<n) number of clocks after timing restoration. Here, n and m are natural numbers.

Because the digital-to-analog converter of the transmitter of the repeater uses the same fixed local oscillator as that of the receiver, the digital-to-analog converter has n system clocks within a predetermined time. However, because the number of valid data generated after the timing restoration is m within the predetermined time and the number of digital-to-analog conversion clocks is n, the timing restoration unit should generate n valid data from m valid data on the contrary to the timing restoration for synchronizing transmission and reception timing clock. Although the same local oscillator is used for the analog-to-digital converter and digital-to-analog converter in this embodiment, the analog-to-digital converter and digital-to-analog converter may use a different local oscillator to each other.

Changing the number of valid data within the predetermined time is referred to as a data rate change. If difference between the number of data before restoration and the number of data after restoration is integer number of times, ‘0’ is simply inserted as many as the integer number and low pass filtering is performed. However, since the timing clock has a difference of a decimal number as the system clock, variable data rate should be converted. The present invention uses a second interpolator for the variable data rate conversion and uses timing information, which is the timing clock information to be restored by the timing restoration unit of the receiver, as clock information for generating a valid data of the second interpolator.

Exemplary embodiments of the present invention will be described in detail hereinafter with reference to the accompanying drawings.

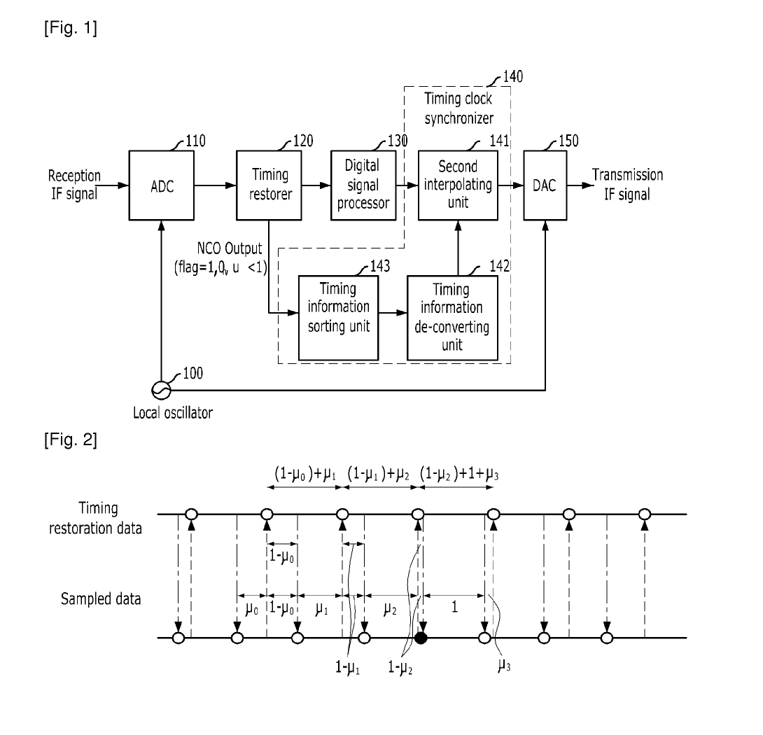

FIG. 1 is a block diagram showing an apparatus for synchronizing a timing clock of a transmission signal and a reception signal in accordance with an embodiment of the present invention and FIG. 2 illustrates timing clock synchronization scheme in accordance with an embodiment of the present invention.

As shown in FIG. 1, the timing clock synchronization apparatus includes a local oscillator 100, an analog-to-digital converter (ADC) 110, a timing restorer 120, a digital signal processor 130, a timing clock synchronizer 140, and a digital-to-analog converter (DAC) 150.

The local oscillator 100 oscillates a constant frequency. The analog-to-digital converter 110 performs sampling of a reception signal according to a local oscillation frequency from the local oscillator 100. The timing restorer 120 restores a timing clock of the reception signal based on the sampling data from the analog-to-digital converter 110. The digital signal processor 130 processes the timing restored signal from the timing restorer 120. The timing clock synchronizer 140 synchronizes the signal of the digital signal processor 130 with the system clock based on timing information transmitted from the timing restorer 120. That is, the timing clock synchronizer 140 synchronizes the timing clock based on the timing restoration signal and the timing information. The digital-to-analog converter 150 converts a digital signal, which is the valid data, into an analog signal based on the frequency from the local oscillator 100.

The timing clock synchronizer 140 in accordance with an embodiment of the present invention includes a second interpolation unit 141 and a timing information de-converting unit 142. The timing information de-converter 142 de-converts the timing information which is Numerically Controlled Oscillator (NCO) transmitted from the timing restoration unit 120. The second interpolator 141 converts “data loaded in the timing restoration clock” from the digital signal processor 130 into “data having a system clock” based on the de-converted timing information from the timing information de-converter 142.

In other words, the second interpolator 141 generates the valid data based on the restored timing restoration signal from the timing restoration unit 120 and the de-converted timing information from the timing information de-converter 142.

Also, the timing clock synchronizer 140 in accordance with an embodiment of the present invention includes a timing information sorting unit 143. The timing information sorting unit 143 sorts the timing information (which is NCO output information) from the timing restoration unit 120 and transfers the sorted timing information to the timing information de-converter 142 in order to maintain the timing restoration data and the timing information from the interpolator in one-to-one correspondence. The timing information sorting unit 143 is used for increasing performance and not related to subject matter of the present invention.

Next, the components as mentioned above will be described in detail hereafter.

First, the local oscillator 100 generates the constant frequency and provides the constant frequency (system clock) to the analog-to-digital converter 110 and the digital-to-analog converter 150 to generate a clock.

The analog-to-digital converter 110 is provided with the constant frequency (system clock) from the local oscillator 100, performs sampling of an input signal in every system clock having a predetermined interval, and transfers the sampling data to the timing restoration unit 120.

The timing restoration unit 120 operates in accordance with the system clock. As shown in FIG. 2, the timing restoration unit 120 receives the sampling data having the predetermined interval from the analog-to-digital converter 110 and restores the timing clock of the reception signal. The timing restoration unit 120 transfers the timing information to the timing information sorting unit 143 of the timing clock synchronizer 140 and transfers the timing restoration data to the digital signal processor 130. Here, the number of the timing restoration data is smaller than the number of the sampling data within the predetermined time.

The digital signal processor 130 receives the timing restoration signal (the timing restoration data) from the timing restoration unit 120 and performs signal processing such as carrier restoration, equalization, and modulation processes, etc.

The timing clock synchronizer 140 receives the timing information (which is an output of NCO) from the timing restoration unit 120 and converts a data loaded in the timing restoration clock into a data having the system clock through the second interpolator 141. NCO output information includes standard data position information

(flag
=1, 0) of a first interpolator (not shown in FIG. 1) included in the timing restoration unit 120 and a decimal place position information
(μₙ
<1) of a data restored from the standard data position information. The timing information de-converter 142 de-converts the NCO output information (which is the timing information). The standard data position information shows whether or not data is generated based on data inputted to the first interpolator of the timing restoration unit 120 as the standard data. That is, if
flag
is ‘1’, valid data that is apart from the data inputted in the second interpolator 141 as
μₙ
is calculated. If
flag
is ‘0’, the valid data is not generated.

$${μ}_{k}^{′} = \frac{( 1 - {μ}_{( n - 1 )} ) + {flag}^{′}}{( 1 - {μ}_{( n - 1 )} ) + {flag}^{′} + {μ}_{n}} \qquad Eq . 1$$

The decimal place position information

μ′ₖ
inputted to the second interpolator 141 is calculated based on Eq. 1 by the timing information de-converter 142.
μₙ
is decimal place position information when one period of the system clock is assumed as ‘1’. As shown in FIG. 2, if
μₙ
is applied in the second interpolator 141,
μₙ
must be calculated by assuming one period of the timing restoration clock as ‘1’. In Eq. 1, has a reverse value, that is, if
flag
is ‘1’,
flag′
is ‘0’ and if
flag
is ‘0’,
flag′
is ‘1’. Although the timing restoration unit 120 reduces the number of the data, the timing clock synchronizer 140 should increase data number reversely.

The digital-to-analog converter 150 receives the constant frequency (system clock) from the local oscillator 100 and converts the valid data into an analog signal.

In FIG. 2, the timing information generated in the timing restorer 120 corresponds to each of timing restoration data in one-to-one. When the timing clock synchronizer 140 uses the timing information, the timing restoration data corresponds to the timing data in one-to-one through the timing information sorting unit 143. That is, the timing information sorter 143 temporally delays the timing information until the timing restoration data is inputted from the timing restorer to the second interpolation unit 141 as a standard data and keeps one-to-one correspondence between the timing restoration data and the timing information. Although the timing information sorting unit 143 is used to raise calculation accuracy, the timing information sorter 143 may be omitted.

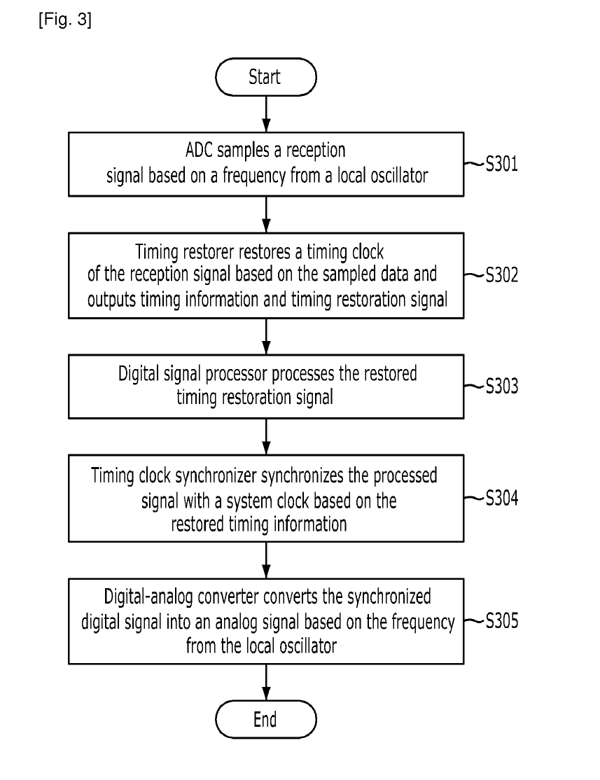

FIG. 3 is a flowchart illustrating a timing clock synchronization method for synchronizing timing clock between a transmission signal and a reception signal in accordance with an embodiment of the present invention. Because the detailed descriptions on embodiment of the timing clock synchronization method is similar to those of the timing clock synchronization apparatus mentioned above, technical features for the timing clock synchronizing method between a transmission signal and a reception signal will be described hereafter.

First, an analog-to-digital converter 110 samples a reception signal based on a frequency (local oscillation frequency) from a local oscillator 100 at step S301.

After, a timing restoration unit 120 restores a timing clock of the reception signal based on the sampling data from the analog-to-digital converter 110 and outputs timing information and a timing restoration signal at step S302.

A digital signal processor 130 processes the timing restoration signal restored in the timing restoration unit 120 at step S303.

A timing clock synchronizer 140 synchronizes the processed signal from the digital signal processor 130 with a system clock based on the timing information restored from the timing restorer 120 at step S304. That is, the timing clock synchronizer 140 synchronizes the timing clock based on the timing restoration signal and the timing information.

A digital-to-analog converter 150 converts the digital signal (which is valid data) synchronized in the timing clock synchronizer 140 into an analog signal based on the frequency from the local oscillator 100 at step S305.

The above-mentioned apparatus may be implemented in hardware, software or combination thereof. In the hardware implementation, the modules used for synchronizing a timing clock between the transmission signal and the reception signal may be implemented with one or more of application-specific integrated circuits (ASIC), digital signal processors (DSP), digital signal processing devices (DSPD), programmable logic devices (PLD), field programmable gate arrays (FPGA), processors, controllers, microcontrollers, microprocessors, other electronic units designed to execute the above-mentioned functions, and combinations thereof. Software codes may be stored in memory units and executed by processors. The memory units may be implemented inside or outside the processors. In this case, the memory units may be connected to the processors through various known devices.

The present application contains a subject matter related to Korean Patent Application Nos. 10-2008-0124308 and 10-2009-0030317, filed in the Korean Intellectual Property Office on Dec. 8, 2008 and Apr. 8, 2009, the entire contents of which is incorporated herein by reference.

While the present invention has been described with respect to the specific embodiments, it will be apparent to those skilled in the art that various changes and modifications may be made without departing from the spirit and scope of the invention as defined in the following claims.

1. An apparatus for synchronizing a timing clock between a transmission signal and a reception signal, comprising:
a timing restorer configured to restore a timing clock based on a digital input data; and
a timing clock synchronizer configured to synchronize the timing clock based on timing information and a timing restoration signal restored in the timing restorer.

2. The apparatus of claim 1, wherein the timing clock synchronizer includes:
a timing information de-converting unit configured to de-convert the timing information transmitted from the timing restorer; and
an interpolating unit configured to generate valid data based on the timing restoration signal restored in the timing restorer and the de-converted timing information de-converted in the timing information de-converter.

3. The apparatus of claim 2, wherein the interpolating unit converts ‘data loaded in the timing restoration clock’ restored in the timing restorer into ‘a data having a system clock’ based on the de-converted timing information from the timing information de-converting unit.

4. The apparatus of claim 2, wherein the timing information restored in the timing restorer includes:
standard data position information
(flag
=1, 0); and
a decimal place position information
(μₙ
<1) of data to be restored from the standard data position information.

5. The apparatus of claim 2, wherein the timing information de-converting calculates the decimal place position information
(μ′ₖ)
base on a following Eq. 1 and transfers the calculated decimal number place information to the interpolating unit, the Eq. 1 being expressed as:
$${μ}_{k}^{′} = \frac{( 1 - {μ}_{( n - 1 )} ) + {flag}^{′}}{( 1 - {μ}_{( n - 1 )} ) + {flag}^{′} + {μ}_{n}}$$
where,
μ′ₖ
denotes decimal place position information where one period of the system clock is assumed to be ‘1’,
flag
denotes standard data position information,
μₙ
denotes decimal place position information of data to be restored from the standard data position information, and
μₙ
is less than 1.

6. The apparatus of claim 2, wherein the timing clock synchronizer further includes:
a timing information sorting unit configured to sort the timing information transmitted from the timing restorer and transfer the sorted timing information to the timing information de-converting unit to maintain a one-to-one correspondence between the timing restoration data and the timing information in the interpolating unit.

7. The apparatus of claim 6, wherein the timing information sorting unit delays the timing information until the timing restoration data transmitted from the timing restorer is inputted to the interpolating unit, and transfers the delayed timing information to timing information de-converting unit.

8. The apparatus of claim 2, further comprising:
a local oscillator configured to generate a constant frequency;
an analog-to-digital converter configured to sample an input signal based on the constant frequency and to transfer the sampled data to the timing restorer; and
a digital-to-analog converter configured to convert the valid data to an analog signal based on the constant frequency.

9. The apparatus of claim 8, wherein the local oscillator is a fixed local oscillator.

10. The apparatus of claim 8, wherein the analog-to-digital converter and the digital-to-analog converter uses the constant frequency from the same local oscillator.

11. The apparatus of claim 8, wherein the analog-to-digital converter and the digital-to-analog converter uses the constant frequency from a different local oscillator from each other.

12. A method for synchronizing a timing clock between a transmission signal and a reception signal, comprising:
sampling the reception signal;
restoring a timing clock based on the sampled data and outputting a timing restoration signal and restored timing information; and
synchronizing the timing clock based on the restored timing information and the timing restoration signal.

13. The method of claim 12, wherein said synchronizing the timing clock includes:
de-converting the restored timing information; and
generating valid data based on the timing restoration signal and the de-converted timing information.

14. The method of claim 13, wherein in said generating valid data, the restored ‘data loaded in the restored timing clock’ are converted into ‘data having a system clock’ based on the de-converted timing information.

15. The method of claim 14, wherein the restored timing information includes:
standard data position information
(flag
=1, 0) and decimal place position information
(μₙ
<1) of data to be restored from the standard data position information.

16. The method of claim 13, wherein said de-converting the resoetored information, the decimal place position information
(μ′ₖ)
base on a following Eq. 1 and transfers the calculated decimal number place information is calculated based on a following Equation as
$${μ}_{k}^{′} = \frac{( 1 - {μ}_{( n - 1 )} ) + {flag}^{′}}{( 1 - {μ}_{( n - 1 )} ) + {flag}^{′} + {μ}_{n}}$$
where,
μ′ₖ
denotes decimal place position information where one period of the system clock is assumed to be ‘1’,
flag
denotes standard data position information,
μₙ
denotes decimal place position information of data to be restored from the standard data position information, and
μₙ
is less than 1.

17. The method of claim 13, wherein said synchronizing the timing clock further includes:
sorting the restored timing information to maintain one-on-one corresponding relation between the timing restored data and the timing information in said generating valid data.

18. The method of claim 17, wherein said sorting the restored timing information includes:
delaying the restored timing information until the restored timing restoration data is inputted to an interpolator, and transmitting the delayed timing information to a de-converting unit.
